(19) United States
(12) Patent Application Publication
(10) Pub. No.: US 2024/0218512 A1
(43) Pub. Date: Jul. 4, 2024

(54) METHODS AND APPARATUS FOR AN ACCUMULATOR

(71) Applicant: ASM IP Holding B.V., Almere (NL)

(72) Inventors: Madhan Kumar Arulanandam, Tempe, AZ (US); Balaji Kannan, Phoenix, AZ (US); Jereld Lee Winkler, Gilbert, AZ (US)

(21) Appl. No.: 18/395,822

(22) Filed: Dec. 26, 2023

Related U.S. Application Data
(60) Provisional application No. 63/477,606, filed on Dec. 29, 2022.

(51) Int. Cl. C23C 16/455

(52) U.S. Cl. CPC C23C 16/45561; C23C 16/45544; C23C 16/45557; C23C 16/45591

(57) ABSTRACT

Various embodiments of the present technology may provide an accumulator having an interior region defined by a plurality of sidewalls. The accumulator may include an inlet disposed in a first sidewall and an outlet disposed within a second sidewall. The accumulator may also include a piston disposed within the interior region and a rod coupled to the piston, wherein the rod extends outside the interior region through a third sidewall.

### CROSS-REFERENCE TO RELATED APPLICATIONS

This application is a nonprovisional of, and claims priority to and the benefit of, U.S. Provisional Patent Application No. 63/477,606, filed Dec. 29, 2022 and entitled “METHODS AND APPARATUS FOR AN ACCUMULATOR,” which is hereby incorporated by reference herein.

### FIELD OF INVENTION

The present disclosure generally relates to an accumulator. More particularly, the present disclosure relates to an accumulator used to provide variable pressures and increases flow rate during a semiconductor manufacturing process.

### BACKGROUND OF THE TECHNOLOGY

For various manufacturing processes, such as atomic layer deposition (ALD) processes and CVD processes, increasing wafer throughput can be achieved by reducing either the precursor pulse time or the purge time. One way to reduce the pulse time is to utilize an accumulator that can be charged during the non-pulsing states of an ALD cycle, which will enable the accumulator to reach a pressure equivalent to that of the precursor set pressure. During pulsing, the charged accumulator will discharge the precursor at a higher flow rate (relative to a system that does not use an accumulator), which is proportional to its pressure, thus minimizing pulse time. However, in a conventional accumulator, the maximum accumulator pressure is always less than or equal to the source vessel set pressure, which puts an upper limit on the flow rate out of the accumulator.

### SUMMARY OF THE INVENTION

Various embodiments of the present technology may provide an accumulator having an interior region defined by a plurality of sidewalls. The accumulator may include an inlet disposed in a first sidewall and an outlet disposed within a second sidewall. The accumulator may also include a plunger disposed within the interior region and a rod coupled to the plunger, wherein the rod extends outside the interior region through a third sidewall.

According to one aspect, an accumulator comprises a body comprising a first surface, a second surface, and a third surface, wherein the first surface, the second surface, and the third surface define an interior region; an inlet coupled to the first surface and arranged adjacent to the second surface; an outlet coupled to the third surface; an apparatus comprising: a plunger disposed within the interior region; and a rod coupled to the plunger, wherein the rod is partially disposed within the interior region; and a valve disposed within the plunger.

In an embodiment of the above accumulator, the first surface comprises a cylindrical tube; the second surface is circular shaped and coupled to a first end of the cylindrical tube; and the second surface is circular shaped and coupled to a second end of the cylindrical tube.

In an embodiment of the above accumulator, the second surface comprises a through-hole arranged at a geometric center of the first surface.

In an embodiment of the above accumulator, the rod is disposed within the through-hole.

In an embodiment of the above accumulator, the interior region has a fixed volume.

In an embodiment of the above accumulator, the cylindrical tube comprises an interior surface having a fixed circumference.

In an embodiment of the above accumulator, the plunger is circular shaped having the fixed circumference and the plunger is in direct contact with the interior surface of the cylindrical tube.

In an embodiment of the above accumulator, the valve comprises a check valve that is responsive to a pressure differential within the interior region.

In an embodiment of the above accumulator, the valve comprises a one-way valve responsive to a control signal.

According to another aspect, a method comprises: flowing a precursor into an accumulator, the accumulator comprising an interior region having a first volume and a first pressure; increasing the first pressure of the accumulator to a second pressure comprising compressing the precursor into a second volume within the interior region, wherein the second volume is less than the first volume; releasing the precursor from the second volume comprising opening a first valve that is coupled to the second volume; flowing the released precursor into a reaction chamber; and flowing additional precursor through the accumulator and into the reaction chamber.

In an embodiment of the above method, the accumulator further comprises a plunger disposed within the interior region, and wherein compressing the precursor comprises moving the plunger from a first position to a second position.

In an embodiment of the above method, the accumulator further comprises a second valve disposed within the plunger and configured to operate according to a pressure differential within the interior region.

In an embodiment of the above method, the method further comprises selecting the second volume based on a desired flow rate.

According to yet another aspect, a system comprises: an accumulator configured to contain gas molecules and comprising: a body comprising an interior region; a first inlet; an outlet; and an apparatus disposed within the interior region and configured to compress the gas molecules; a reaction chamber coupled to the accumulator; and a second valve interposed between the outlet of the accumulator and the reaction chamber.

In an embodiment of the above system, the apparatus comprises: a plunger disposed within the interior region; and a rod coupled to the plunger, wherein the rod is partially disposed within the interior region.

In an embodiment of the above system, the system further comprises a first valve disposed within the plunger, and wherein the first valve comprises a check valve that is responsive to a pressure differential within the interior region.

In an embodiment of the above system, the system further comprises a pressure sensor in fluid communication with and configured to measure a pressure within the interior region.

In an embodiment of the above system, the apparatus comprises: a bellow in fluid communication with the inlet and the outlet and configured to contain the gas molecules; and a rod coupled to the bellow.

In an embodiment of the above system, the apparatus comprises: a bellow in fluid communication with the first inlet and the outlet and configured to contain the gas molecules; and a second inlet in fluid communication with the interior region.

In an embodiment of the above system, the apparatus comprises: a bellow disposed within the interior region; and a second inlet in fluid communication with the bellow; wherein the first inlet and the outlet are in fluid communication with the interior region.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with various embodiments of the present technology;

FIGS. 2A-2C representatively illustrate an accumulator in accordance with an exemplary embodiment of the present technology;

FIG. 2D representatively illustrates a cross sectional view of the accumulator of FIG. 2A;

FIG. 2E representatively illustrates a side view of the accumulator of FIG. 2A;

FIGS. 3A-3B illustrate an accumulator in accordance with an alternative embodiment of the present technology;

FIGS. 4A-4B illustrate an accumulator in accordance with an alternative embodiment of the present technology;

FIGS. 5A-5B illustrate an accumulator in accordance with an alternative embodiment of the present technology;

FIG. 6 is a graph that illustrates the relationship between accumulator pressure and flow rate in accordance with embodiments of the present technology;

FIG. 7 is a graph that illustrates the relationship between flow rate and pressure at varying positions in accordance with embodiment of the present technology;

FIG. 8 is a graph illustrating the accumulator pressure of the present invention compared to a conventional accumulator; and

FIG. 9 is a graph illustrating a precursor dose delivered in accordance with the present invention compared to a precursor dose of a conventional system.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, valves, precursors, and delivery lines. Further, the present technology may employ any number of controllers and/or control systems. Further, the present technology may employ any type of actuation.

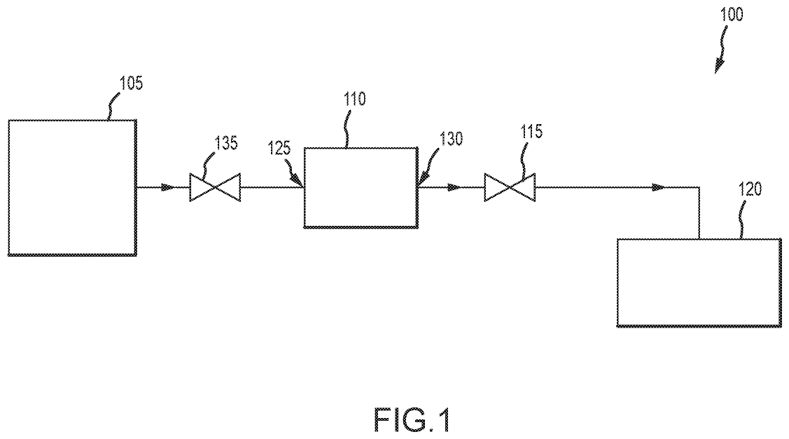

Referring to FIG. 1, an exemplary system 100 may comprise a source vessel 105 configured to contain or hold a chemistry (e.g., a precursor or a reactant) used in the semiconductor manufacturing process. The chemistry in the source vessel 105 may be in a solid, liquid, or gas phase initially. In the case of a solid or a liquid chemistry, the solid or liquid may be converted to a gas phase. For example, the system 100 may further comprise various devices and/or systems to convert a solid or a liquid to a gas. The conversion to a gas phase may occur within the source vessel 105. The system 100 may further comprise an accumulator 110 and a reactor 120. In addition, the system 100 may further comprise a plurality of valves, such as a first valve 135 and a second valve 115.

In various embodiments, the system 100 may further comprise a controller (not shown) configured to receive signals from components of the system 100, such as the first and second valves 135, 115. In addition, the controller may transmit signals to components in the system 100, such as the first and second valves 135, 115 and the accumulator 110.

In various embodiments, the reactor 120 may be configured for processing a substrate, such as a wafer (not shown). For example, the reactor 120 may comprise a reaction chamber (not shown) to receive the wafer for processing and gas distribution system (not shown). The gas distribution system may be configured to deliver a precursor or reactant (or a gas mixture of precursor and an inert gas) to the reaction chamber. The reactor 120 may further comprise a susceptor (not shown) to support the substrate during processing. In various embodiments, the susceptor may comprise heating elements (not shown) and/or cooling elements (not shown). In various embodiments, the susceptor may comprise electrodes (not shown) capable of providing an electrostatic chucking function. Alternatively, the susceptor may be configured for other types of chucking, such as vacuum chucking or mechanical chucking. In some embodiments, the gas distribution system may be positioned above the reaction chamber and susceptor. However, in other embodiments, the gas distribution system may be positioned lateral to the susceptor. The reactor 120 may be configured to provide any number of desired processing parameters, such as pressure and temperature, to achieve a desired process result.

In various embodiments, the accumulator 110 may be connected to (e.g., in fluid communication with) the source vessel 105. For example, the accumulator 110 may be connected to the source vessel 105 with an interconnect line suitable for flowing a gas. In various embodiments, the accumulator 110 may be arranged between the source vessel 105 and the reactor 120. In particular, the accumulator 110 may be arranged between the first valve 135 and the second valve 115. For example, the accumulator 110 may be downstream from the source vessel 105 and the first valve 115, and the second valve 115 and the reactor 120 may be downstream from the accumulator 110. In various embodiments, the accumulator 110 may comprise a first inlet 125 and an outlet. The first inlet 125 may be coupled to (in fluid communication with) the first valve 135 and the outlet 130 may be coupled to (in fluid communication with) the second valve 115.

In various embodiments, the accumulator 110 may further comprise an apparatus 220 configured to compress gas molecules within the accumulator 110. For example, the apparatus 220 may be actuated to move within the accumulator 110. In some embodiments, the apparatus 220 itself contains the gas molecules, and in other embodiments, the gas molecules are outside of the apparatus 220. In various embodiments, the frequency of movement of the apparatus 200 and/or the starting and ending position of apparatus 220 may be determined based on a desired pressure within the accumulator 110 and/or a desired dose of the chemistry to the reactor 120. For example, the controller may transmit a control signal to the accumulator 110 and/or apparatus 220 that corresponds to a distance of movement of the apparatus 220, a volume of gas flow into the apparatus 220 or accumulator 110, amount of compression of the apparatus 220, and/or the ending position of the apparatus 220.

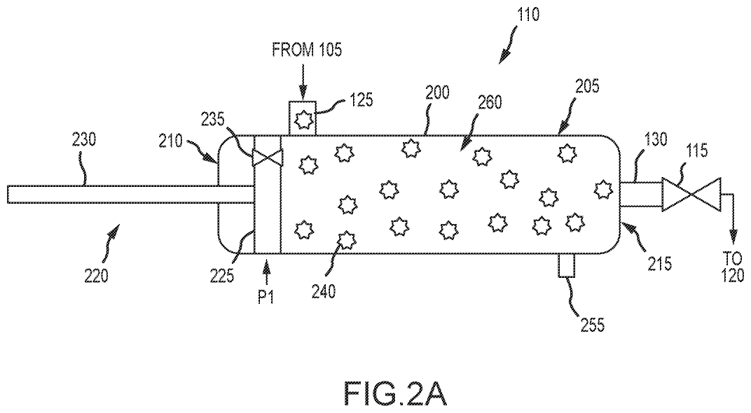

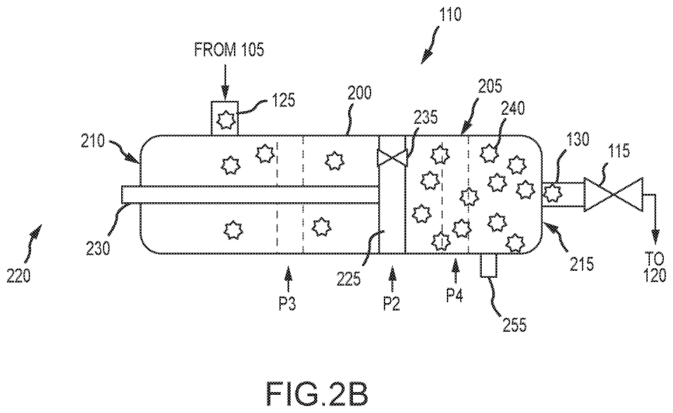

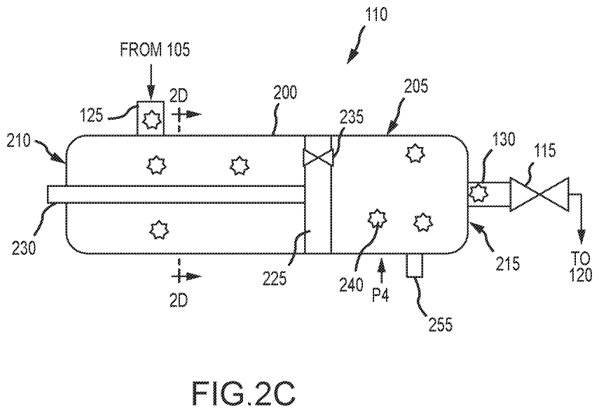

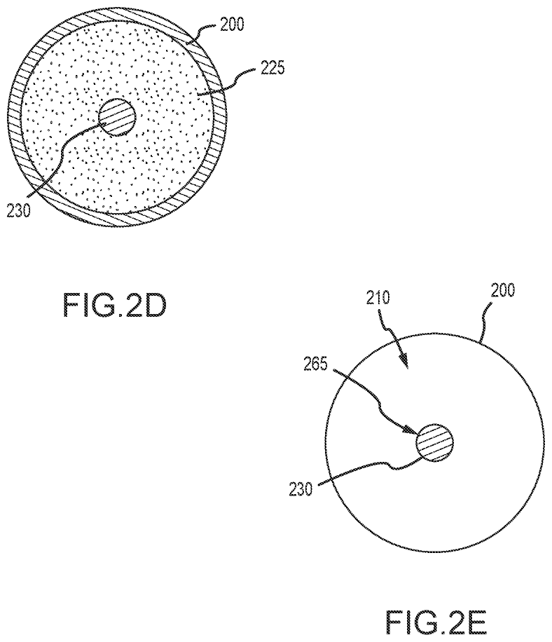

In various embodiments, and referring to FIGS. 2A-C and 5A-B, the accumulator 110 may comprise a body 200 configured to contain gas molecules 240. The body may comprise a first surface 205, a second surface 210, and a third surface 215. The second surface 210 may be coupled to a first end of the first surface 205 and the third surface 215 may be coupled to a second end of the first surface 205. The second and third surfaces 210, 215 may be arranged in parallel with each other and perpendicular to the first surface 205. The first surface 210 may define a first end of the body 200 and the second surface 215 may define a second end of the body 200. The body 200 may further comprise an interior region 260 defined by the first surface 205, the second surface 210, and the third surface 215. The first surface 205 may comprise a cylindrical tube having a circumference, and the second and third surfaces 210, 215 may have a circular shape having the same circumference.

In various embodiments, the system 100 may further comprise a pressure sensor 255, coupled to the body 200 and configured to measure a pressure within the interior region 260. In an exemplary embodiment, the pressure sensor 255 may comprise a pressure transducer, however, in other embodiments, the pressure sensor 255 may comprise any system or device suitable for measuring or detecting pressure. The pressure sensor 255 may be configured to transmit a sensor signal corresponding to the pressure in the interior region 260 to the controller. The controller may utilize the sensor signal to operate the accumulator 110.

Referring to FIGS. 2A-2E, the apparatus 220 may comprise a plunger 225 disposed within the interior region 260. The plunger 225 may have a same shape as the accumulator 110. For example, in a case where the body 200 of the accumulator 110 is cylindrically-shaped, the plunger 225 may have a circumference that is approximately the same as a circumference of an interior wall of the body 200. In addition, the plunger 225 may separate the interior region 260 into two volumes and may be sized to create a seal between the two volumes.

In the present embodiment, the apparatus 220 may further comprise a rod 230 connected to the plunger 225. The rod 230 may extend outward from the body 200 of the accumulator 110 through a though-hole 265 in the second surface 210. In the present case, the outlet 130 may be arranged at the third surface 215 and in fluid communication with the interior region 260. In the present case, the first inlet 125 may be arranged at the first surface 205 and adjacent to the second surface 210.

In the present embodiment, the accumulator 110 may further comprise a third valve 235 disposed within the plunger 225. The third valve 235 may be arranged to enable the flow of gas molecules 240 from one side of the plunger 225 to an opposite side of the plunger 225. The third valve 235 may comprise a mechanical valve (e.g., a check valve) that operates based on a pressure differential between one side of the third valve 235 (and plunger 225) and an opposite side of the third valve 235 (and plunger 225). In other embodiments, the third valve 235 may be electrically operated via a signal from the controller. In other embodiments, the third valve 235 comprise a pneumatic valve, a solenoid valve, a hydraulic valve, or the like.

In the present embodiment, the plunger 225 and rod 230 may be actuated by any suitable device or system, such as a mechanical actuation, hydraulic actuation, pneumatic actuation or the like, and such device or system may operate according to (and/or be triggered by) the control signal from the controller.

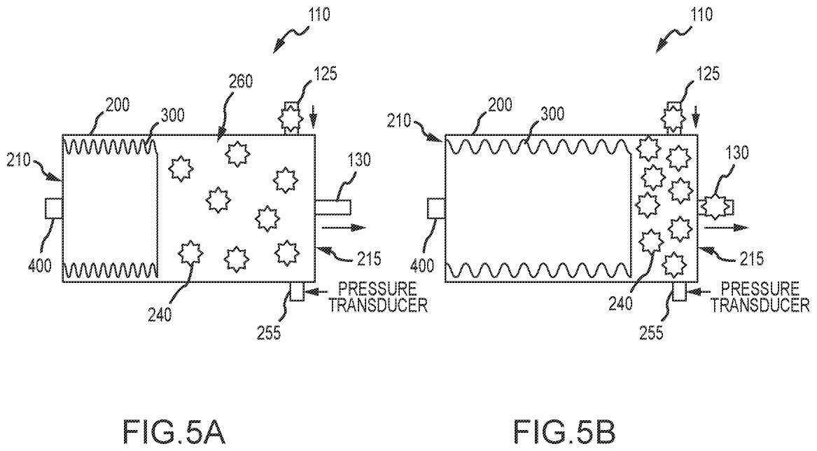

In an alternative embodiment, and referring to FIGS. 5A-B, the apparatus 220 comprises a bellow 300 configured to contract and expand within the interior region 260 of the accumulator 110. In the present case, the gas molecules are outside of the bellow 300. In particular, the bellow 300 may be arranged within the interior region 260 to compress the gas molecules 240 into a space that is near or adjacent to the outlet 130 when the bellow 300 is expanded. The bellow 300 may comprise an expandable material, such as a rubber material, and/or be configured to expand.

In the present embodiment, the apparatus 220 may further comprise a second inlet 400. The second inlet 400 may be attached to and in fluid communication with the bellow 300. The second inlet 400 may be configured to flow air or a compressed gas into the bellow 300 to expand the bellow 300. In the present embodiment, the system 100 may further comprise a compressed air source (not shown) coupled to the second inlet 400. The second inlet 400 may also be configured to pull air or gas out of the bellow 300 to contract the bellow 300. Alternatively, the present embodiment may comprise a second outlet (not shown) attached to and in fluid communication with the bellow 300 to contract the bellow 300. For example, the second outlet may be coupled to a vacuum source.

In the present embodiment, the first inlet 125 may be arranged at the first surface 205 and adjacent to the third surface 215. In particular, the first inlet 125 may be arranged in a location such that gas flowing into the interior region 260, via the first inlet, is not impeded or blocked by the bellow 300.

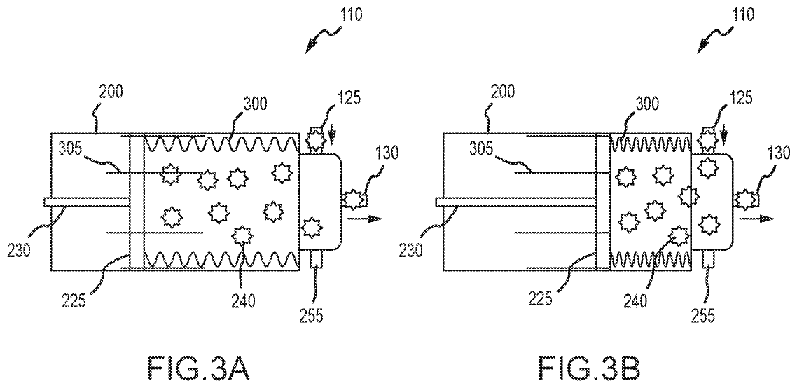

In alternative embodiments, and referring to FIGS. 3A-B and 4A-B, the apparatus 220 may comprise a combination of the plunger 225 and the bellow 300, wherein the gas molecules 240 are contained within the bellow 300. In one embodiment, and referring to FIGS. 3A-B, the plunger 225 and rod 230 are used to contract and expand the bellow 300. As described above, the rod 230 and plunger 225 may be actuated by any suitable system, device, or method.

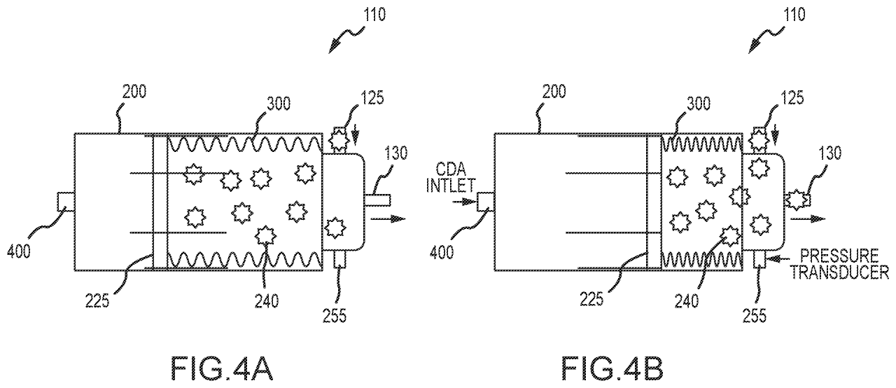

In another embodiment, and referring to FIGS. 4A-B, the plunger 225 and bellow 300 may be actuated with air (i.e., pneumatically). In the present case, the accumulator 110 can be pressurized with compressed air to compress the bellow 300 (FIG. 4B) and expand the bellow 300 by applying a vacuum. In this case, the accumulator 110 may comprise the second inlet 400 to flow gas to the interior region 260 that is opposite the bellow 300. For example, the second inlet 400 may be disposed at the second sidewall and opposite from the outlet 130 and/or the bellow 300.

In the present embodiments, the bellow 300 may comprise a portion that extends outside the body 200 of the accumulator 110. In an exemplary embodiment, the first inlet 125 and the outlet 130 may be directly coupled to the portion of the bellow 300 that extends outside the body 200. In addition, the pressure sensor 255 may be directly coupled to the portion of the bellow 300 that extends outside the body 200.

Alternatively, the bellow 300 may be completely enclosed within the body 200 of the accumulator 100. In such a case, the first inlet 125 and the outlet 130 may be coupled to the body 200 and extend into the interior region 260 to couple to the bellow 300. In addition, the pressure sensor 255 or a portion of the pressure sensor 255 may be arranged inside the body 200 in the interior region 260 and coupled directly to the bellow 330.

According to the present embodiments, the accumulator 110 may further comprise guide rails 305 disposed within the interior region 260 and along the interior sidewalls of the first surface 205. The guide rails 305 may be configured to promote or maintain mechanical stability of the plunger 225 when the plunger 225 and bellow 300 are actuated. The guide rails 305 may be arranged perpendicular to the plunger 225 and may be in contact with the plunger 225.

According to the present embodiments, the accumulator 110 may further comprise a second outlet (not shown) configured to pull the air out of the interior region, thus expanding the bellow 300. In such a case, the second outlet may be coupled to a vacuum source.

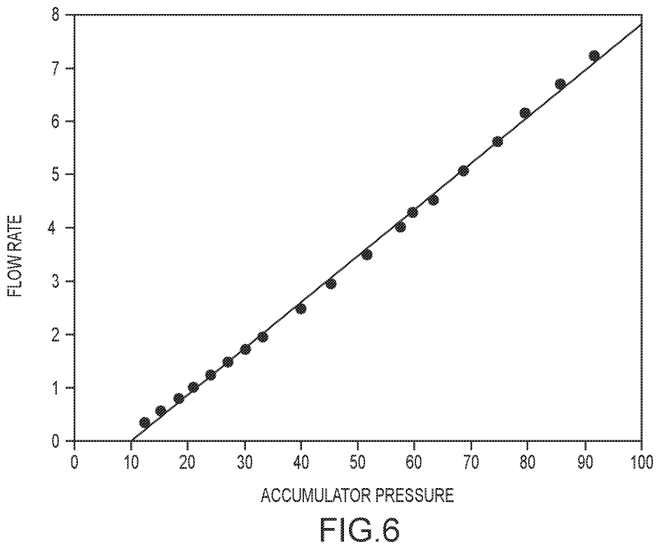

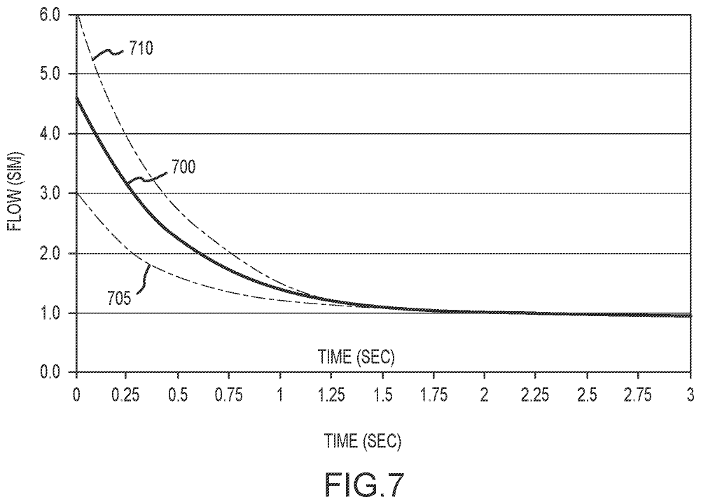

In operation, and referring to the FIGS. 1 and 2A-C, the accumulator 110 may undergo a charging state in which the gas molecules 240 are flowed from the source vessel 105 to the accumulator 110 via the first inlet 125. In the charging state, the first valve 135 is open and the second valve 115 is closed. In addition, the third valve 235 is closed. This allows the pressure in the accumulator 110 to increase. Once the pressure in the accumulator 110 is at or near the pressure of the source vessel 105, the first valve 135 is closed and the plunger 225 is moved to compress the gas molecules. For example, the plunger 225 is actuated via the rod 230 from an initial position P1 to an ending position (e.g., positions P2, P3 or P4). The amount of actuation or compression of gas molecules may be based on a desired pressure within the accumulator 110. As the volume of the compressed gas molecules decreases, the pressure increases. For example, FIG. 2A illustrates the plunger 225 at the initial position and having a first pressure and a first volume, and FIG. 2B illustrates the plunger 225 at the ending position, where the compressed gas molecules to the right of the plunger 225 are compressed to a second volume and have a second pressure that is higher than the first pressure. In some embodiments, the pressure sensor 255 may be used to determine when the pressure in the accumulator 110 has reached a desired pressure. For example, the controller may utilize the received sensor signal from the pressure sensor 255 to determine when the desired pressure is reached and, in response, discontinue actuation of the plunger 225. Alternatively or additionally, the plunger 225 may be moved to a set (predetermined) position that corresponds to a particular pressure. For example, the pressure of the accumulator 110 when the plunger 225 is at position P4 is greater than the pressure when the plunger 225 is a position P2. Similarly, the pressure of the accumulator 110 when the plunger 225 is at position P3 is less than the pressure when the plunger 225 is at position P2. The desired pressure may be based on a desired flow rate out of the accumulator 110. The higher the pressure, the higher the flow rate (e.g., as illustrated in FIG. 6), therefore, desired pressure may be computed or determined (e.g., by the controller) based on the desired flow rate. Moreover, the flow rate may correlate with the position of the plunger 225. For example, and referring to FIG. 7, line 700 may correspond to position P2, line 705 may correspond to position P3, and line 710 may correspond to position P4.

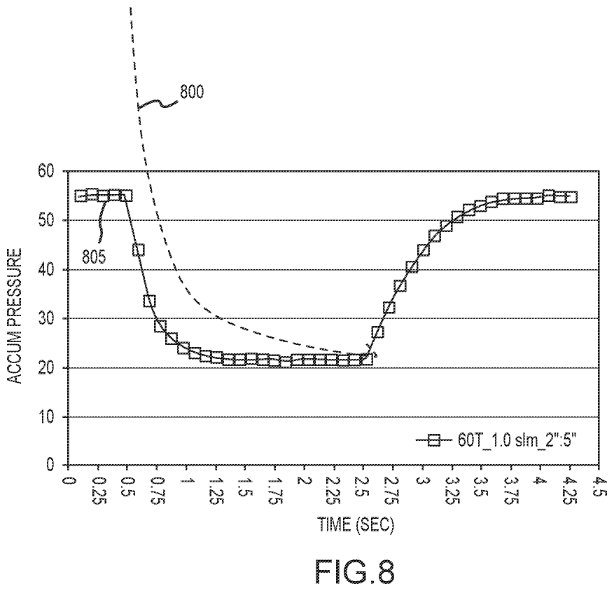

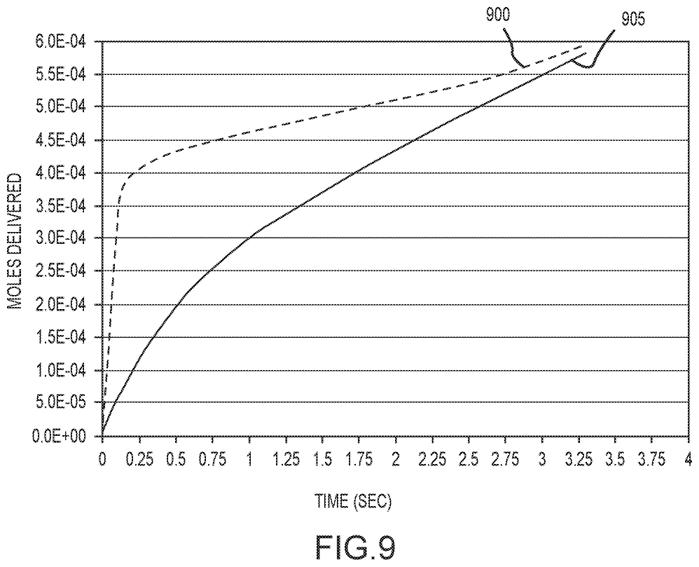

After the pressure in the accumulator has been increased to the desired pressure, the system 100 may open the second valve 115, thereby releasing the precursor gas molecules to flow into the reactor 120. Due to the higher accumulator pressure, the same dose of precursor can be delivered to the reactor 120 in less time than a conventional system. For example, and referring to FIG. 9, line 900 represents the amount of precursor delivered according to embodiment of the present technology, while line 905 represents the amount of precursor delivered from a conventional accumulator. In addition, and referring to FIG. 8, the pressure of the accumulator 110 before and during release (illustrated as line 800) is higher initially compared to a conventional accumulator (illustrated as line 805), and decreases at a higher rate than the conventional accumulator.

After the precursor gas molecules are released, the system 100 may enter a steady state. During the steady state, the first and third valves 135, 235 may be open to allow precursor gas molecules to flow from the source vessel 105 through the accumulator 110 and into the reactor 120. The first valve 135 may stay open to provide continuous gas flow or may be pulsed to provide a pulsed gas flow. The third valve 235 may open automatically when the pressure on the left side of the plunger 225 is greater than the pressure on the right side of the plunger 225.

At the end of the steady state, the plunger 225 may be moved back to the initial (start) position P1 and then the second and third valves 115, 235 may be closed again to restart the charging state.

Similarly, and referring to FIGS. 1 and 3A-3B, the accumulator 110 may undergo a charging state in which the gas molecules 240 are flowed from the source vessel 105 to the accumulator 110 via the first inlet 125. In the charging state, the first valve 135 is open and the second valve 115 is closed. This allows the pressure in the accumulator 110 to increase. Once the pressure in the accumulator 110 is at or near the pressure of the source vessel 105, the first valve 135 is closed and the plunger 225 is moved to compress the gas molecules. For example, the plunger 225 is actuated via the rod 230 from an initial position (e.g., as illustrated in FIG. 3A) to an ending position (e.g., as illustrated in FIG. 3B). In the initial position, the accumulator 110 has a first volume and a first pressure, and in the ending position, the accumulator 110 has a second volume and a second pressure. The amount of actuation or compression of gas molecules may be based on a desired pressure within the accumulator 110. As the volume of the compressed gas molecules decreases, the pressure increases. In some embodiments, the pressure sensor 255 may be used to determine when the pressure in the accumulator 110 has reached a desired pressure. For example, the controller may utilize the received sensor signal from the pressure sensor 255 to determine when the desired pressure is reached and, in response, discontinue actuation of the plunger 225. Alternatively or additionally, the plunger 225 may be moved to a set (predetermined) position that corresponds to a particular pressure. The desired pressure may be based on a desired flow rate out of the accumulator 110. The higher the pressure, the higher the flow rate (e.g., as illustrated in FIG. 6), therefore, desired pressure may be computed or determined (e.g., by the controller) based on the desired flow rate. Moreover, the flow rate may correlate with the position of the plunger 225.

After the pressure in the accumulator has been increased to the desired pressure, the system 100 may open the second valve 115, thereby releasing the precursor gas molecules to flow into the reactor 120. Due to the higher pressure, the same dose of precursor can be delivered to the reactor 120 in less time than a conventional system. For example, and referring to FIG. 9, line 900 represents the amount of precursor delivered according to embodiment of the present technology, while line 905 represents the amount of precursor delivered from a conventional accumulator. In addition, and referring to FIG. 8, the pressure of the accumulator 110 before and during release (illustrated as line 800) is higher initially compared to a conventional accumulator (illustrated as line 805), and decreases at a higher rate than the conventional accumulator.

After the precursor gas molecules are released, the system 100 may enter a steady state. During the steady state, the first valve 135 may be open to allow precursor gas molecules to flow from the source vessel 105 through the accumulator 110 and into the reactor 120. The first valve 135 may stay open to provide continuous gas flow or may be pulsed to provide a pulsed gas flow.

At the end of the steady state, the plunger 225 may be moved back to the initial (start) position and then the second valve 115 may be closed again to restart the charging state.

Similarly, and referring to FIGS. 1 and 4A-4B, the accumulator 110 may undergo a charging state in which the gas molecules 240 are flowed from the source vessel 105 to the accumulator 110 via the first inlet 125. In the charging state, the first valve 135 is open and the second valve 115 is closed. This allows the pressure in the accumulator 110 to increase. Once the pressure in the accumulator 110 is at or near the pressure of the source vessel 105, the first valve 135 is closed and the plunger 225 is moved to compress the gas molecules. For example, the plunger 225 is actuated, in this case by flowing compressed air into the accumulator 110 and compressing the bellow 300, from an initial position (e.g., as illustrated in FIG. 4A) to an ending position (e.g., as illustrated in FIG. 4B). In the initial position, the accumulator 110 has a first volume and a first pressure, and in the ending position, the accumulator 110 has a second volume and a second pressure. The amount of actuation or compression of gas molecules may be based on a desired pressure within the accumulator 110. As the volume of the compressed gas molecules decreases, the pressure increases. In some embodiments, the pressure sensor 255 may be used to determine when the pressure in the accumulator 110 has reached a desired pressure. For example, the controller may utilize the received sensor signal from the pressure sensor 255 to determine when the desired pressure is reached and, in response, discontinue actuation of the plunger 225. Alternatively or additionally, the plunger 225 may be moved to a set (predetermined) position within the accumulator 110 that corresponds to a particular pressure. The desired pressure may be based on a desired flow rate out of the accumulator 110. The higher the pressure, the higher the flow rate (e.g., as illustrated in FIG. 6), therefore, desired pressure may be computed or determined (e.g., by the controller) based on the desired flow rate. Moreover, the flow rate may correlate with the position of the plunger 225.

After the pressure in the accumulator has been increased to the desired pressure, the system 100 may open the second valve 115, thereby releasing the precursor gas molecules to flow into the reactor 120. Due to the higher pressure, the same dose of precursor can be delivered to the reactor 120 in less time than a conventional system. For example, and referring to FIG. 9, line 900 represents the amount of precursor delivered according to embodiment of the present technology, while line 905 represents the amount of precursor delivered from a conventional accumulator. In addition, and referring to FIG. 8, the pressure of the accumulator 110 before and during release (illustrated as line 800) is higher initially compared to a conventional accumulator (illustrated as line 805), and decreases at a higher rate than the conventional accumulator.

After the precursor gas molecules are released, the system 100 may enter a steady state. During the steady state, the first valve 135 may be open to allow precursor gas molecules to flow from the source vessel 105 through the accumulator 110 and into the reactor 120. The first valve 135 may stay open to provide continuous gas flow or may be pulsed to provide a pulsed gas flow.

At the end of the steady state, the plunger 225 may be moved back to the initial (start) position and then the second valve 115 may be closed again to restart the charging state.

Similarly, and referring to FIGS. 1 and 5A-5B, the accumulator 110 may undergo a charging state in which the gas molecules 240 are flowed from the source vessel 105 to the accumulator 110 via the first inlet 125. In the charging state, the first valve 135 is open and the second valve 115 is closed. This allows the pressure in the accumulator 110 to increase. Once the pressure in the accumulator 110 is at or near the pressure of the source vessel 105, the first valve 135 is closed and the bellow 300 is expanded to compress the gas molecules. For example, the bellow 300 is expanded, in this case by flowing compressed air into the bellow 300, from an initial position (e.g., as illustrated in FIG. 5A) to an ending position (e.g., as illustrated in FIG. 5B). In the initial position, the accumulator 110 has a first volume and a first pressure, and in the ending position, the accumulator 110 has a second volume and a second pressure. The amount of expansion of the bellow 300 and/or compression of the gas molecules may be based on a desired pressure within the accumulator 110. As the volume of the compressed gas molecules decreases, the pressure increases. In some embodiments, the pressure sensor 255 may be used to determine when the pressure in the accumulator 110 has reached a desired pressure. For example, the controller may utilize the received sensor signal from the pressure sensor 255 to determine when the desired pressure is reached and, in response, discontinue expansion of the bellow 300. Alternatively or additionally, the bellow 300 may be expanded to a set (predetermined) volume within the accumulator 110 that corresponds to a particular pressure. The desired pressure may be based on a desired flow rate out of the accumulator 110. The higher the pressure, the higher the flow rate (e.g., as illustrated in FIG. 6), therefore, desired pressure may be computed or determined (e.g., by the controller) based on the desired flow rate. Moreover, the flow rate may correlate with the amount of expansion of the bellow 300.

After the pressure in the accumulator has been increased to the desired pressure, the system 100 may open the second valve 115, thereby releasing the precursor gas molecules to flow into the reactor 120. Due to the higher pressure, the same dose of precursor can be delivered to the reactor 120 in less time than a conventional system. For example, and referring to FIG. 9, line 900 represents the amount of precursor delivered according to embodiment of the present technology, while line 905 represents the amount of precursor delivered from a conventional accumulator. In addition, and referring to FIG. 8, the pressure of the accumulator 110 before and during release (illustrated as line 800) is higher initially compared to a conventional accumulator (illustrated as line 805), and decreases at a higher rate than the conventional accumulator.

After the precursor gas molecules are released, the system 100 may enter a steady state. During the steady state, the first valve 135 may be open to allow precursor gas molecules to flow from the source vessel 105 through the accumulator 110 and into the reactor 120. The first valve 135 may stay open to provide continuous gas flow or may be pulsed to provide a pulsed gas flow.

At the end of the steady state, the bellow 300 may be compressed back to the initial (start) position and then the second valve 115 may be closed again to restart the charging state.

In various embodiments, during the charging state, the pressure in the accumulator 110 is increased to a pressure that is greater than the pressure in the source vessel 105. This increase in pressure provides a higher flow rate out of the accumulator 110 and into the reactor 120, and thus is able to deliver the precursor dose within a shorter time (compared to a conventional system where the maximum accumulator pressure is less than or equal to the source vessel pressure). For example, by increasing the pressure of the accumulator 110 to ten times the initial pressure, the same precursor dose can be delivered in 1/10^{th} of the delivery time for a conventional system. This shorter delivery time may provide higher wafer throughput.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An accumulator, comprising:
a body comprising a first surface, a second surface, and a third surface, wherein the first surface, the second surface, and the third surface define an interior region;
an inlet coupled to the first surface and arranged adjacent to the second surface;
an outlet coupled to the third surface;
an apparatus comprising:
a plunger disposed within the interior region; and
a rod coupled to the plunger, wherein the rod is partially disposed within the interior region; and
a valve disposed within the plunger.

2. The accumulator according to claim 1, wherein:
the first surface comprises a cylindrical tube;
the second surface is circular shaped and coupled to a first end of the cylindrical tube; and
the second surface is circular shaped and coupled to a second end of the cylindrical tube.

3. The accumulator according to claim 1, wherein the second surface comprises a through-hole arranged at a geometric center of the first surface.

4. The accumulator according to claim 3, wherein the rod is disposed within the through-hole.

5. The accumulator according to claim 1, wherein the interior region has a fixed volume.

6. The accumulator according to claim 2, wherein the cylindrical tube comprises an interior surface having a fixed circumference.

7. The accumulator according to claim 6, wherein the plunger is circular shaped having the fixed circumference and the plunger is in direct contact with the interior surface of the cylindrical tube.

8. The accumulator according to claim 1, wherein the valve comprises a check valve that is responsive to a pressure differential within the interior region.

9. The accumulator according to claim 1, wherein the valve comprises a one-way valve responsive to a control signal.

10. A method, comprising:
flowing a precursor into an accumulator, the accumulator comprising an interior region having a first volume and a first pressure;
increasing the first pressure of the accumulator to a second pressure comprising compressing the precursor into a second volume within the interior region, wherein the second volume is less than the first volume;
releasing the precursor from the second volume comprising opening a first valve that is coupled to the second volume;
flowing the released precursor into a reaction chamber; and
flowing additional precursor through the accumulator and into the reaction chamber.

11. The method according to claim 10, wherein the accumulator further comprises a plunger disposed within the interior region, and wherein compressing the precursor comprises moving the plunger from a first position to a second position.

12. The method according to claim 11, wherein the accumulator further comprises a second valve disposed within the plunger and configured to operate according to a pressure differential within the interior region.

13. The method according to claim 10, further comprising selecting the second volume based on a desired flow rate.

14. A system, comprising:
an accumulator configured to contain gas molecules and comprising:
a body comprising an interior region;
a first inlet;
an outlet; and
an apparatus disposed within the interior region and configured to compress the gas molecules;
a reaction chamber coupled to the accumulator; and
a second valve interposed between the outlet of the accumulator and the reaction chamber.

15. The system according to claim 14, wherein the apparatus comprises:
a plunger disposed within the interior region; and
a rod coupled to the plunger, wherein the rod is partially disposed within the interior region.

16. The system according to claim 15, further comprising a first valve disposed within the plunger, and wherein the first valve comprises a check valve that is responsive to a pressure differential within the interior region.

17. The system according to claim 14, further comprising a pressure sensor in fluid communication with and configured to measure a pressure within the interior region.

18. The system according to claim 14, wherein the apparatus comprises:
a bellow in fluid communication with the inlet and the outlet and configured to contain the gas molecules; and
a rod coupled to the bellow.

19. The system according to claim 14, wherein the apparatus comprises:
a bellow in fluid communication with the first inlet and the outlet and configured to contain the gas molecules; and
a second inlet in fluid communication with the interior region.

20. The system according to claim 14, wherein the apparatus comprises:
a bellow disposed within the interior region; and
a second inlet in fluid communication with the bellow;
wherein the first inlet and the outlet are in fluid communication with the interior region.
